(19) United States
(12) Patent Application Publication
(10) Pub. No.: US 2026/0075830 A1
(43) Pub. Date: Mar. 12, 2026

(54) MEMORY DEVICE INCLUDING BLOCK SELECTION CIRCUIT

(71) Applicant: SK hynix Inc., Icheon-si (KR)

(72) Inventors: Chang Woo KANG, Icheon-si (KR); Jin Ho KIM, Icheon-si (KR)

(21) Appl. No.: 19/053,299

(22) Filed: Feb. 13, 2025

(30) Foreign Application Priority Data
Sep. 10, 2024 (KR) 10-2024-0122774

(51) Int. Cl. H10B 43/40; G11C 16/08; H10B 41/41

(52) U.S. Cl. CPC H10B 43/40; G11C 16/08; H10B 41/41

(57) ABSTRACT

A memory device includes a first semiconductor layer including a slimming area, a first cell area and a second cell area arranged on both sides of the slimming area in a first direction, and a second semiconductor layer including a pass transistor region vertically overlapping with the slimming area, and a first block selection circuit region and a second block selection circuit region connected to the pass transistor region through a plurality of block selection signal lines, wherein the pass transistor region includes a first portion, a second portion and a third portion disposed on both sides of the first portion in a second direction perpendicular to the first direction, and wherein the first block selection circuit region and the second block selection circuit region are respectively disposed on both sides of the first portion of the pass transistor region in the first direction.

### CROSS-REFERENCE TO RELATED APPLICATION

The present application claims priority under 35 U.S.C. § 119(a) to Korean patent application number 10-2024-0122774 filed in the Korean Intellectual Property Office on Sep. 10, 2024, which is incorporated herein by reference in its entirety.

### TECHNICAL FIELD

The embodiments of the present disclosure relate to a memory device including a block selection circuit.

### BACKGROUND

There has been proposed a three-dimensional memory device having memory cells arranged three-dimensionally. Three-dimensional memory devices may have the advantage of being able to implement a greater capacity in the same area by vertically stacking memory cells and providing high performance and superior power efficiency. A memory device may include a plurality of memory blocks and a block selection circuit for selecting one of the plurality of memory blocks.

### SUMMARY

Embodiments of the disclosure may provide a memory device including a block selection circuit.

Embodiments of the disclosure may provide a memory device including a first semiconductor layer including a slimming area, a first cell area and a second cell area arranged on both sides of the slimming area in a first direction, and a second semiconductor layer including a pass transistor region vertically overlapping with the slimming area, and a first block selection circuit region and a second block selection circuit region connected to the pass transistor region through a plurality of block selection signal lines, wherein the pass transistor region includes a first portion, and a second portion and a third portion disposed on both sides of the first portion in a second direction perpendicular to the first direction, and wherein the first block selection circuit region and the second block selection circuit region are respectively disposed on both sides of the first portion of the pass transistor region in the first direction.

Embodiments of the disclosure may provide a memory device including a first semiconductor layer including a first slimming area, a first plane area including a first cell area and a second cell area respectively disposed on both sides of the first slimming area in a first direction, a second slimming area adjacent to the first slimming area in a second direction perpendicular to the first direction, and a second plane area including a third cell area and a fourth cell area respectively disposed on both sides of the second slimming area in the first direction, and a second semiconductor layer including a first pass transistor region vertically overlapping with the first slimming area, a second pass transistor region vertically overlapping with the second slimming area, and a first block selection circuit region, a second block selection circuit region and a third block selection circuit region connected to the first pass transistor region and the second pass transistor region through a plurality of block selection signal lines, wherein the first pass transistor region includes a first portion, a second portion and a third portion disposed on both sides of the first portion in the second direction, wherein the second pass transistor region includes a fourth portion, and a fifth portion between the first pass transistor region and the fourth portion, wherein the first block selection circuit region and the second block selection circuit region are disposed on both sides of the first portion of the first pass transistor region in the first direction, respectively, and wherein the third block selection circuit region is disposed on one side of the fifth portion of the second pass transistor region in the first direction.

Embodiments of the disclosure may provide a memory device including a first semiconductor layer including a first slimming area, a first plane area including a first cell area and a second cell area respectively disposed on both sides of the first slimming area in a first direction, a second slimming area adjacent to the first slimming area in a second direction, and a second plane area including a third cell area and a fourth cell area respectively disposed on both sides of the second slimming area in the first direction, and a second semiconductor layer including a first pass transistor region vertically overlapping with the first slimming area, a second pass transistor region vertically overlapping with the second slimming area, and a first block selection circuit region and a second block selection circuit region connected to the first pass transistor region and the second pass transistor region through a plurality of block selection signal lines, wherein the second pass transistor region includes a first portion, and a second portion between the first pass transistor region and the first portion, and wherein the first block selection circuit region and the second block selection circuit region are respectively disposed on both sides of the second portion of the second pass transistor region in the first direction.

According to embodiments of the present disclosure, it is possible to provide a memory device including a block selection circuit.

### BRIEF DESCRIPTION OF THE DRAWINGS

FIG. 1 is a schematic block diagram of a memory device according to embodiments of the present disclosure.

FIG. 2 is a block diagram of a row decoder of FIG. 1.

FIG. 3 is a perspective view of a memory device according to embodiments of the present disclosure.

FIG. 4 is a schematic plan view of a first semiconductor layer according to an embodiment of the present disclosure.

FIG. 5 is a plan view illustrating block selection signal lines and connection lines according to an embodiment of the present disclosure.

FIG. 6 is a plan view illustrating an arrangement of pass transistor groups and block selection switch units according to an embodiment of the present disclosure.

FIG. 7 is a plan view illustrating block signal selection lines according to an embodiment of the present disclosure.

FIG. 8 to FIG. 11 are schematic plan views of a first semiconductor layer according to embodiments of the present disclosure.

FIG. 12 is a perspective view of a memory device according to embodiments of the present disclosure.

FIG. 13 to FIG. 14 are schematic plan views of a first semiconductor layer according to embodiments of the present disclosure.

### DETAILED DESCRIPTION

Hereinafter, various embodiments of the present disclosure will be described in detail with reference to accompanying drawings. The specific structural or functional descriptions of embodiments are provided as examples to explain the concepts disclosed herein. The embodiments or examples according to the concepts of the present disclosure may be implemented in various forms, and the scope of the present disclosure is not limited to the embodiments or examples described herein.

The same hatching shown throughout the drawings may indicate corresponding or identical areas in the drawings, and does not indicate materials associated with the corresponding areas.

When one element is described as being “connected” or “coupled” to another element, the elements may be directly connected or directly coupled, or may be connected or coupled through one or more intermediate elements between the elements. When two elements are described as being “directly connected” or “directly coupled,” one element is directly connected or directly coupled to the other element without any intermediate element between the two elements.

When one element is described as being disposed “over” or “under” another element, the elements may be in direct contact with each other, or an intermediate element may be disposed between the elements. When elements are described as being “on both sides” of a third element along a direction, the elements may be spaced apart in the direction and arranged to be adjacent to or contact the opposite sides of the third element.

Terms such as “vertical,” “horizontal,” “upper,” “lower,”, “up”, “down”, “top,” “bottom,” “front,” “back,” “side,” “left and right,” “column,” “row,” “level,” and other relative spatial relationships or directions are used only for the purpose of ease of description or reference to the drawings, and are not limiting to any specific meaning. Other spatial relationships or directions not shown in the drawings or described in the specification are also possible within the scope of the present specification.

Terms such as “first” and “second” may be used to distinguish different elements and do not imply size, order, priority, quantity, or importance of the elements. For example, in some embodiments, a first element may be referred to as a second element, and in other embodiments, a second element may be referred to as a first element.

When an element included in embodiments in the present specification is described in the singular form, the element may be interpreted to include a plurality of elements performing the same or similar functions.

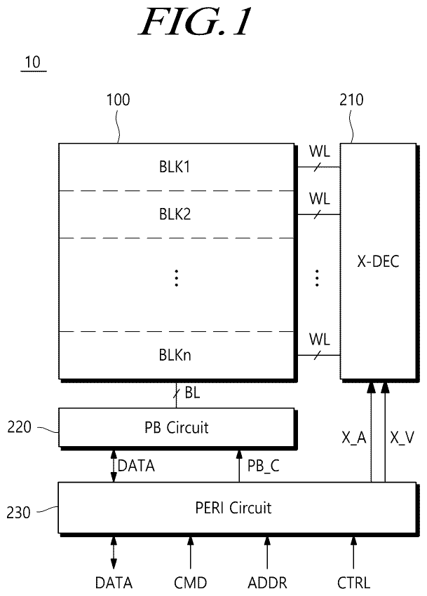

FIG. 1 is a schematic block diagram of a memory device according to embodiments of the present disclosure.

Referring to FIG. 1, a memory device 10 according to an embodiment of the present disclosure may include a memory cell array 100, a row decoder (e.g., X-DEC) 210, a page buffer circuit (e.g., PB Circuit) 220, and a peripheral circuit (e.g., PERI Circuit) 230.

The memory cell array 100 may include a plurality of memory blocks BLK1-BLKn. Each of the memory blocks BLK1-BLKn may include a plurality of memory cells. The memory cell may be, for example, a flash memory cell. Hereinafter, memory cells are described as NAND flash memory cells, but the present disclosure is not limited thereto. The memory cells may also be resistive memory cells such as ReRAM, PRAM, or MRAM.

The memory blocks BLK1-BLKn may be connected to the row decoder 210 through word lines WL. The memory blocks BLK1-BLKn may be connected to the page buffer circuit 220 through a plurality of bit lines BL.

The row decoder 210 may select one of a plurality of memory blocks BLK1-BLKn included in the memory cell array 100 in response to a row address X_A provided from a peripheral circuit 230. The row decoder 210 may transfer an operating voltage X_V provided from the peripheral circuit 230 to word lines WL of the selected memory block.

The page buffer circuit 220 may receive a page buffer control signal PB_C from the peripheral circuit 230, and may transmit and receive a data signal DATA to and from the peripheral circuit 230. The page buffer circuit 220 may control bit lines BL arranged in the memory cell array 100 in response to the page buffer control signal PB_C. For example, the page buffer circuit 220 may detect data stored in a memory cell of the memory cell array 100 by detecting a signal of a bit line BL of the memory cell array 100 in response to the page buffer control signal PB_C, and may transmit a data signal DATA to the peripheral circuit 230 according to the detected data. The page buffer circuit 220 may apply a signal to the bit line BL based on a data signal DATA received from the peripheral circuit 230 in response to the page buffer control signal PB_C, and may write data to the memory cell of the memory cell array 100 accordingly. The page buffer circuit 220 may write data to the memory cell connected to the word line activated by the row decoder 210 or read data therefrom.

The peripheral circuit 230 may receive a command signal CMD, an address signal ADDR, and a control signal CTRL from the outside of the memory device 10, and may transmit and receive data DATA with a device outside of the memory device 10, such as a memory controller. The peripheral circuit 230 may output signals for writing data to the memory cell array 100 or reading data from the memory cell array 100, such as a row address X_A and a page buffer control signal PB_C, based on a command signal CMD, an address signal ADDR, and a control signal CTRL. The peripheral circuit 230 may generate various voltages required by the memory device 10, including an operating voltage X_V.

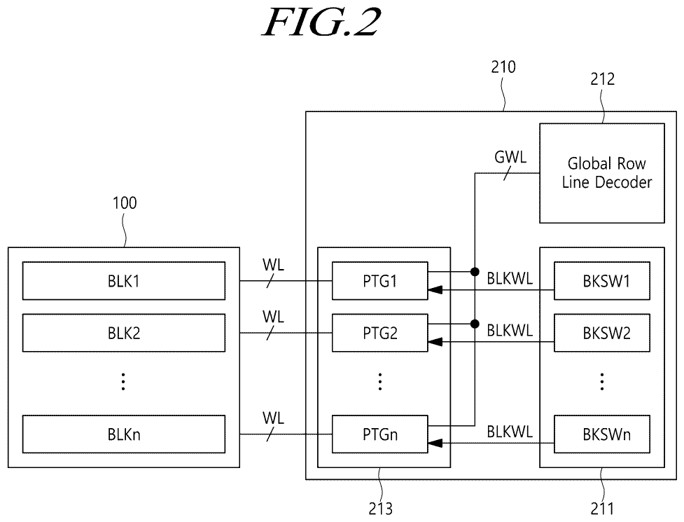

FIG. 2 is a block diagram of a row decoder of FIG. 1.

Referring to FIG. 2, a row decoder 210 may include a block selection circuit 211, a global row line decoder 212, and a pass transistor circuit 213.

The block selection circuit 211 may include a plurality of block selection switches BKSW1-BKSWn corresponding to a plurality of memory blocks BLK1-BLKn, respectively. The block selection switches BKSW1-BKSWn may be connected to the pass transistor circuit 213 through block selection signal lines BLKWL1-BLKWLn. One of the plurality of block selection switches BKSW1-BKSWn may be selected in response to a row address received from a peripheral circuit. The selected block selection switch may output an activated block selection signal to the block selection signal line BLKWL.

The global row line decoder 212 may be connected to the pass transistor circuit 213 via the global word lines GWL. The global row line decoder 212 may receive operating voltages from a peripheral circuit and output the operating voltages to the global word lines GWL in response to a control signal received from the peripheral circuit. The global row line decoder 212 may include a plurality of switching elements which transmit the operating voltages to the global word lines GWL.

The pass transistor circuit 213 may include a plurality of pass transistor groups PTG1-PTGn corresponding to a plurality of memory blocks BLK1-BLKn. Each pass transistor group may include a plurality of pass transistors connected to the word lines WL of the corresponding memory block.

The pass transistor groups PTG1-PTGn may be connected to the block selection switches BKSW1-BKSWn respectively through the block selection signal lines BLKWL1-BLKWLn. The gate electrodes of the pass transistors included in each pass transistor group may be commonly connected to one block selection signal line. If the block selection signal provided to the pass transistor group through the block selection signal line is activated, the pass transistors included in the pass transistor group may be turned on.

Each of the pass transistor groups PTG1-PTGn may be connected to the global row line decoder 212 via the global word lines GWL. The global word lines GWL may be commonly connected to the plurality of pass transistor groups PTG1-PTGn. That is, the plurality of pass transistor groups PTG1-PTGn may share the global word lines GWL.

One pass transistor group selected from among the pass transistor groups PTG1-PTGn, i.e., a pass transistor group receiving a block selection signal activated from a block selection circuit 211, may transmit operating voltages provided from a global row line decoder 212 to a corresponding memory block through word lines WL.

Hereinafter, in the attached drawings, two directions parallel to the upper surface of the first semiconductor layer or the second semiconductor layer will be defined as a first direction HD1 and a second direction HD2, respectively, and a direction protruding vertically from the upper surface of the first semiconductor layer and the second semiconductor layer will be defined as the vertical direction VD. For example, the first direction HD1 may be the extension direction of word lines, and the second direction HD2 may be the extension direction of bit lines. The first direction HD1 and the second direction HD2 may intersect each other perpendicularly. The vertical direction VD may be orthogonal to the first direction HD1 and the second direction HD2.

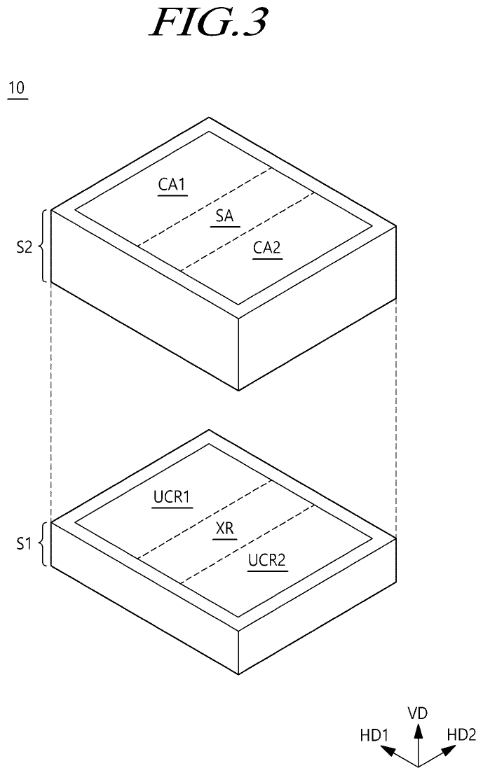

FIG. 3 is a perspective view of a memory device according to embodiments of the present disclosure.

Referring to FIG. 3, a memory device 10 may include a first semiconductor layer S1 and a second semiconductor layer S2. The first semiconductor layer S1 and the second semiconductor layer S2 may overlap with each other in the vertical direction VD. For example, the first semiconductor layer S1 may be disposed below the second semiconductor layer S2 in the vertical direction VD.

In FIG. 3, the first semiconductor layer S1 and the second semiconductor layer S2 may be spaced apart from each other in the vertical direction VD, but this is for the purpose of assisting in understanding, and it should be understood that an upper surface of the first semiconductor layer S1 and a lower surface of the second semiconductor layer S2 may be in contact with each other.

In one embodiment, a row decoder (210 of FIG. 1), a page buffer circuit (220 of FIG. 1), and a peripheral circuit (230 of FIG. 1) may be disposed on the first semiconductor layer S1, and a memory cell array (110 of FIG. 1) may be disposed on the second semiconductor layer S2.

In the second semiconductor layer S2, a plurality of word lines may extend in a first direction HD1, and a plurality of bit lines may extend in a second direction HD2. In an embodiment, the second semiconductor layer S2 may include a first cell area CA1, a second cell area CA2, and a slimming area SA. The first cell area CA1 and the second cell area CA2 may be disposed on both sides of the slimming area SA in the first direction HD1, respectively.

Although not shown, a plurality of word lines may be stacked in a vertical direction VD in the first and second cell areas CA1 and CA2, and the slimming area SA to form a stack. The word lines may be combined with semiconductor pillars penetrating the stack in a vertical direction VD to form memory cells arranged three-dimensionally. The plurality of word lines may be implemented in a step or stair shape in the slimming area SA.

The first semiconductor layer S1 may include a substrate, and a row decoder, a page buffer circuit, and a peripheral circuit formed in the first semiconductor layer S1 by forming semiconductor elements such as transistors and a pattern for wiring the semiconductor elements on the substrate.

The first semiconductor layer S1 may include a first under cell region UCR1, which overlaps with the first cell area CA1 in the vertical direction VD, a second under cell region UCR2, which overlaps with the second cell area CA2 in the vertical direction VD, and a pass transistor region XR, which overlaps with the slimming area SA in the vertical direction VD. The first under cell region UCR1 and the second under cell region UCR2 may be respectively disposed on both sides of the pass transistor region XR in the first direction HD1.

The first semiconductor layer S1 and the second semiconductor layer S2 may be fabricated on a single wafer. After the first semiconductor layer S1 is first formed, the second semiconductor layer S2 may be built up on the first semiconductor layer S1. In such an embodiment, the memory device 10 may be described as having a Peri-Under-Cell (PUC) structure.

The first semiconductor layer S1 and the second semiconductor layer S2 may be bonded to each other by a wafer bonding technique after being manufactured on different wafers. In these embodiments, the memory device 10 may be described as having a Peri-Over-Cell (POC) structure.

The memory device 10 according to the present disclosure may be provided as a PUC structure or a POC structure.

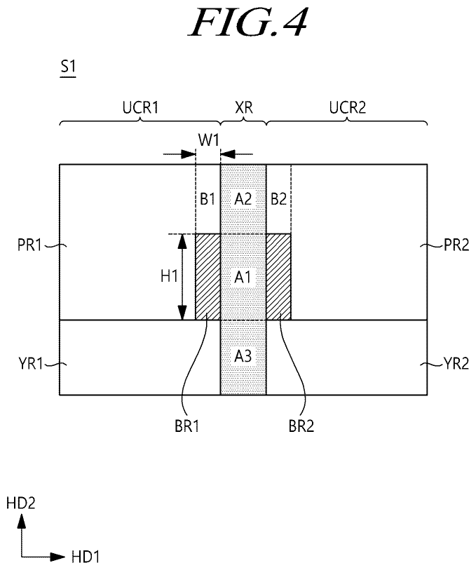

FIG. 4 is a schematic plan view of a first semiconductor layer according to an embodiment of the present disclosure.

Referring to FIG. 4, a first semiconductor layer S1 may include a pass transistor region XR, a first under cell region UCR1 and a second under cell region UCR2 disposed on both sides of the pass transistor region XR in the first direction HD1.

The pass transistor region XR may be a region where a pass transistor circuit is located, and the pass transistor circuit may be included in the pass transistor region XR. The pass transistor region XR may be connected to the first and second cell areas CA1 and CA2 of FIG. 3 through a plurality of word lines (not shown).

The pass transistor region XR may be divided into a first portion A1, a second portion A2, and a third portion A3. The second portion A2 and the third portion A3 may be disposed on both sides of the first portion A1 in the second direction HD2, respectively. The first portion A1 may be a central portion of the pass transistor region XR in the second direction HD2, and the second portion A2 and the third portion A3 may be arranged to be adjacent to opposite edge portions of the pass transistor region XR in the second direction HD2.

The first block selection circuit region BR1 and the second block selection circuit region BR2 may be respectively disposed on both sides of the first portion A1 of the pass transistor region XR in the first direction HD1.

The first and second block selection circuit regions BR1 and BR2 may be regions where the block selection circuit is located, and the block selection circuit may be divided into two parts and included in the first block selection circuit region BR1 and the second block selection circuit region BR2. The first and second block selection circuit regions BR1 and BR2 may be connected to the pass transistor region XR through a plurality of block selection signal lines (not shown).

The dimension of the first block selection circuit region BR1 in the first direction HD1 may have a size of W1, and the dimension of the first block selection circuit region BR1 in the second direction HD2 may have a size of H1. The dimensions of the second block selection circuit region BR2 may be substantially the same as the dimensions of the first block selection circuit region BR1. The dimensions of the first and second block selection circuit region BR1 and BR2 in the second direction HD2 may have substantially the same size as the dimension of the first portion A1 of the pass transistor region XR in the second direction HD2.

The first block selection circuit region BR1 may be included in the first under cell region UCR1, and the second block selection circuit region BR2 may be included in the second under cell region UCR2.

The first under cell region UCR1 may include a first block selection circuit region BR1, a first peripheral circuit region PR1, and a first page buffer region YR1. The second under cell region UCR2 may include a second block selection circuit region BR2, a second peripheral circuit region PR2, and a second page buffer region YR2.

The first page buffer region YR1 and the second page buffer region YR2 are regions where the page buffer circuit is located, and the page buffer circuit may be divided into two parts and included in the first page buffer region YR1 and the second page buffer region YR2. The first and second page buffer regions YR1 and YR2 may be connected to the first and second cell areas CA1 and CA2 respectively of FIG. 3 through a plurality of bit lines (not shown).

In an embodiment, the first page buffer region YR1 and the second page buffer region YR2 may be respectively disposed on both sides of the third portion A3 of the pass transistor region XR in the first direction HD1.

In an embodiment, the dimension of the first and second page buffer regions YR1 and YR2 in the second direction HD2 may be substantially the same as the dimension of the third portion A3 of the pass transistor region XR in the second direction HD2. In an embodiment, the dimension of the first page buffer region YR1 in the first direction HD1 may be substantially the same as the dimension of the first under cell region UCR1 in the first direction HD1, and the dimension of the second page buffer region YR2 in the first direction HD1 may be substantially the same as the dimension of the second under cell region UCR2 in the first direction HD1.

The first peripheral circuit region PR1 and the second peripheral circuit region PR2 are regions where peripheral circuits are located, and part or all of the peripheral circuits may be included in the first and second peripheral circuit regions PR1 and PR2.

The first peripheral circuit region PR1 may be the remaining portion of the first under cell region UCR1 excluding the first block selection circuit region BR1 and the first page buffer region YR1. The second peripheral circuit region PR2 may be the remaining portion of the second under cell region UCR2 excluding the second block selection circuit region BR2 and the second page buffer region YR2.

The first peripheral circuit region PR1 may include a first region B1 overlapping with the first block selection circuit region BR1 in the second direction HD2. The second peripheral circuit region PR2 may include a second region B2 overlapping with the second block selection circuit region BR2 in the second direction HD2. The first region B1 and the second region B2 may each contact both sides of the second portion A2 of the pass transistor region XR in the first direction HD1.

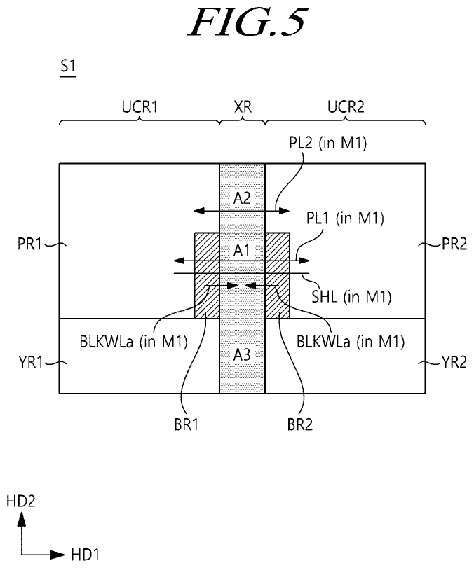

FIG. 5 is a plan view illustrating block selection signal lines and connection lines according to an embodiment of the present disclosure.

Referring to FIG. 5, a first semiconductor layer S1 may include a first wiring layer M1, and there may be disposed block selection signal lines BLKWa, first and second connection lines PL1 and PL2, and a shield line SHL on or in the first wiring layer M1.

Each of the block selection signal lines BLKWLa may extend from one of the first and second block selection circuit regions BR1 and BR2 along the first direction HD1 to the first portion A1 of the pass transistor region XR. The block selection signal lines BLKWLa may be disposed on both sides of the first portion A1 of the pass transistor region XR.

The connection lines PL1 and PL2 may connect the first peripheral circuit region PR1 and the second peripheral circuit region PR2. The connection lines PL1 and PL2 may include a first connection line PL1 and a second connection line PL2.

The first connection line PL1 may cross the first portion A1 of the pass transistor region XR and the first and second block selection circuit regions BR1 and BR2 in the first direction HD1. The second connection line PL2 may cross the second portion A2 of the pass transistor region XR in the first direction HD1.

The shield line SHL may be disposed between the first connection line PL1 and the block selection signal lines BLKWLa. The shield line SHL may serve to prevent interference between the first connection line PL1 and the block selection signal lines BLKWLa, and a constant voltage may be applied to the shield line SHL. The constant voltage may include a ground voltage.

Unlike the present disclosure, in comparative examples, the block selection circuit region may be disposed not only on both sides of a first portion of a pass transistor region, but also on both sides of a second portion of the pass transistor region. In such cases, since the block selection signal lines are disposed not only on both sides of the first portion of the pass transistor region but also on both sides of the second portion of the pass transistor region, an additional shield line is required to be formed to prevent interference between the block selection signal lines arranged on both sides of the second portion of the pass transistor region and the second connection line. However, the addition of the shield line may cause a wiring bottleneck. The wiring bottleneck may be resolved by increasing the size of the memory device or forming an additional wiring layer, but if the size of the memory device increases, then the net die may decrease. In addition, if an additional wiring layer is formed, the number of process steps increases, which may increase manufacturing time and cost.

According to embodiments of the present disclosure, the block selection circuit region may be disposed on both sides of the first portion A1 of the pass transistor region XR, and the block selection circuit region may be not arranged on both sides of the second portion A2 of the pass transistor region XR, so that the block selection signal line may be not disposed on both sides of the second portion A2 of the pass transistor region XR. Therefore, since there is no need to additionally form a shield line next to the second connection line PL2, the occurrence of a wiring bottleneck may be prevented.

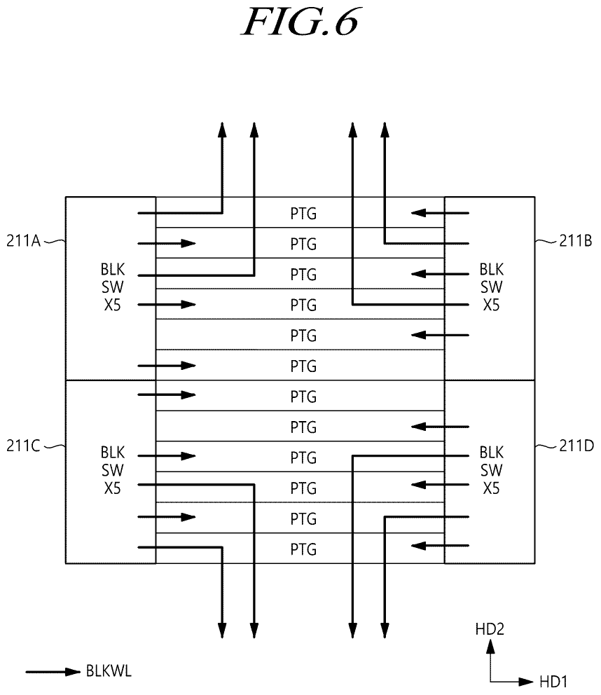

FIG. 6 is a plan view illustrating an arrangement of pass transistor groups and block selection switch units according to an embodiment of the present disclosure.

Referring to FIG. 6, a plurality of pass transistor groups PTG may be disposed in a row and arranged in the second direction HD2, and the block selection switches may be grouped in groups of five to form the first, second, third, and fourth block selection switch units 211A, 211B, 211C and 211D. The first and second block selection switch units 211A and 211B may be disposed on both sides of the upper six pass transistor groups PTG, respectively, and the third and fourth block selection switch units 211C and 211D may be arranged on both sides of the lower six pass transistor groups PTG, respectively.

In FIG. 6, one block selection switch unit includes five block selection switches, and six pass transistor groups PTG are arranged between two block selection switch units spaced apart in the first direction HD1, but other embodiments are not limited thereto. For example, one block selection switch unit may include k (k is a natural number greater than or equal to 2) block selection switches, and r (r is a natural number greater than or equal to 2) pass transistor groups may be arranged between the two block selection switch units on either side of the pass transistor groups.

Referring again to FIG. 6, among the 20 block selection signal lines BLKWL connected to the 20 block selection switches included in the first, second, third and fourth block selection switch units 211A, 211B, 211C and 211D, 12 block selection signal lines BLKWL may be respectively connected to 12 neighboring pass transistor groups PTG in the first direction HD1. Among the remaining 8 block selection signal lines BLKWL, 4 block selection signal lines BLKWL may be respectively routed upward along the second direction HD2 to connect to the pass transistor groups not illustrated, and the other 4 block selection signal lines BLKWL may be respectively routed downward along the second direction HD2 to connect to the pass transistor groups not illustrated.

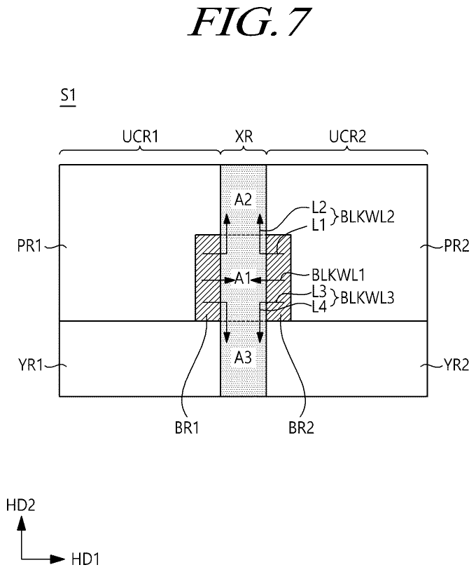

FIG. 7 is a plan view illustrating block signal selection lines according to an embodiment of the present disclosure.

Referring to FIG. 7, block selection signal lines may include first block selection signal lines BLKWL1, second block selection signal lines BLKWL2, and third block selection signal lines BLKWL3.

The first block selection signal lines BLKWL1 may be connected to the first portion A1 of the pass transistor region XR. The second block selection signal lines BLKWL2 may be connected to the second portion A2 of the pass transistor region XR. The third block selection signal lines BLKWL3 may be connected to the third portion A3 of the pass transistor region XR.

In a plan view, the first block selection signal line BLKWL1 may extend from one of the first and second block selection circuit regions BR1 and BR2 along the first direction HD1 to the first portion A1 of the pass transistor region XR.

In a plan view, the second block selection signal line BLKWL2 may include a first line portion L1 extending from one of the first and second block selection circuit regions BR1 and BR2 along the first direction HD1 to the first portion A1 of the pass transistor region XR, and a second line portion L2 extending from the first portion A1 of the pass transistor region XR along the second direction HD2 to the second portion A2 of the pass transistor region XR.

In a plan view, the third block selection signal line BLKWL3 may include a third line portion L3 extending from one of the first and second block selection circuit regions BR1 and BR2 along the first direction HD1 to the first portion A1 of the pass transistor region XR, and a fourth line portion L4 extending from the first portion A1 of the pass transistor region XR along the second direction HD2 to the third portion A3 of the pass transistor region XR.

Although not illustrated, the first block selection signal line BLKWL1, the first line portion L1 of the second block selection signal line BLKWL2 and the third line portion L3 of the third block selection signal line BLKWL3, which all extend in the first direction HD1, may be arranged in a different wiring layer from the second line portion L2 of the second block selection signal line BLKWL2 and the fourth line portion L4 of the third block selection signal line BLKWL3 which extend in the second direction HD2. For example, the first semiconductor layer S1 may include a first wiring layer and a second wiring layer arranged at different heights vertically, and the first block selection signal line BLKWL1, the first line portion L1 of the second block selection signal line BLKWL2 and the third line portion L3 of the third block selection signal line BLKWL3 may be disposed in the first wiring layer, and the second line portion L2 of the second block selection signal line BLKWL2 and the fourth line portion L4 of the third block selection signal line BLKWL3 may be disposed in the second wiring layer.

In a plan view, the second line portion L2 of the second block selection signal line BLKWL2 and the fourth line portion L4 of the third block selection signal line BLKWL3, which originate at a center the first portion A1 of the pass transistor region XR, may extend in opposite direction along the second direction HD2.

Since the second line portion L2 of the second block selection signal line BLKWL2 and the fourth line portion L4 of the third block selection signal line BLKWL3 extend to opposite sides, the second line portions L2 of the N second block selection signal lines BLKWL2 and the fourth line portions L4 of the N third block selection signal lines BLKWL3 may all be disposed in an area corresponding to N times the wiring pitch.

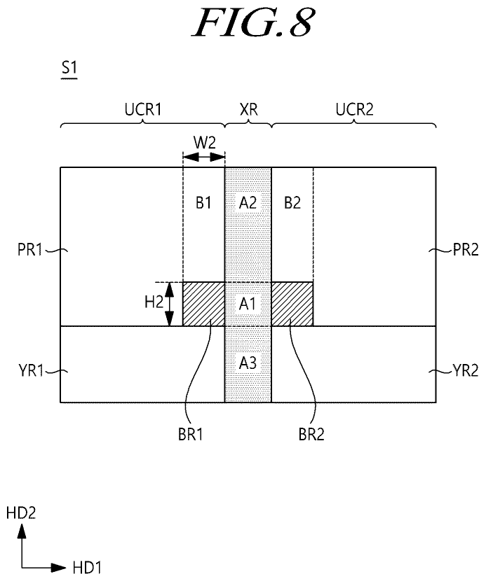

FIGS. 8 to 11 are schematic plan views of a first semiconductor layer according to embodiments of the present disclosure.

Referring to FIG. 8, a dimension of a first block selection circuit region BR1 in the first direction HD1 may be W2, and the dimension of the first block selection circuit region BR1 in the second direction D2 may be H2. W2 is larger than W1 of FIG. 4, and H2 is smaller than H1 of FIG. 4. By increasing the number of block selection switches included in one block selection switch unit, the dimension of the first block selection circuit region BR1 in the first direction HD1 may be increased, and the dimension of the first block selection circuit region BR1 in the second direction HD2 may be decreased. The dimensions of the second block selection circuit region BR2 may be substantially the same as the dimensions of the first block selection circuit region BR1.

As the dimensions of the first and second block selection circuit regions BR1 and BR2 in the second direction HD2 decreases, the dimensions of the first and second regions B1 and B2 in the second direction HD2 may increase. Accordingly, the number of second connection lines crossing the second portion A2 of the pass transistor region XR may be increased.

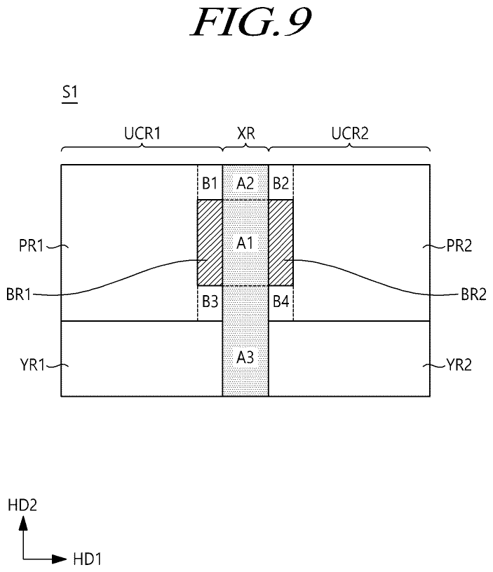

Referring to FIG. 9, a first peripheral circuit region PR1 may include a first region B1 and a third region B3 disposed on both sides of the first block selection circuit region BR1 in the second direction HD2.

The first region B1 may overlap with the first block selection circuit region BR1 in the second direction HD2, and may overlap with the second portion A2 of the pass transistor region XR in the first direction HD1. The third region B3 may overlap with the first block selection circuit region BR1 in the second direction HD2, and may overlap with the third portion A3 of the pass transistor region XR in the first direction HD1.

The second peripheral circuit region PR2 may include a second region B2 and a fourth region B4 disposed on both sides of the second block selection circuit region BR2 in the second direction HD2.

The second region B2 may overlap with the second block selection circuit region BR2 in the second direction HD2, and may overlap with the second portion A2 of the pass transistor region XR in the first direction HD1. The fourth region B4 may overlap with the second block selection circuit region BR2 in the second direction HD2, and may overlap with the third portion A3 of the pass transistor region XR in the first direction HD1.

The first block selection circuit region BR1 and the first page buffer region YR1 may be spaced apart from each other in the second direction HD2, and a third region B3 of the first peripheral circuit region PR1 may be positioned between the first block selection circuit region BR1 and the first page buffer region YR1 in the second direction HD2.

The second block selection circuit region BR2 and the second page buffer region YR2 may be spaced apart from each other in the second direction HD2, and a fourth region B4 of the second peripheral circuit region PR2 may be positioned between the second block selection circuit region BR2 and the second page buffer region YR2 in the second direction HD2.

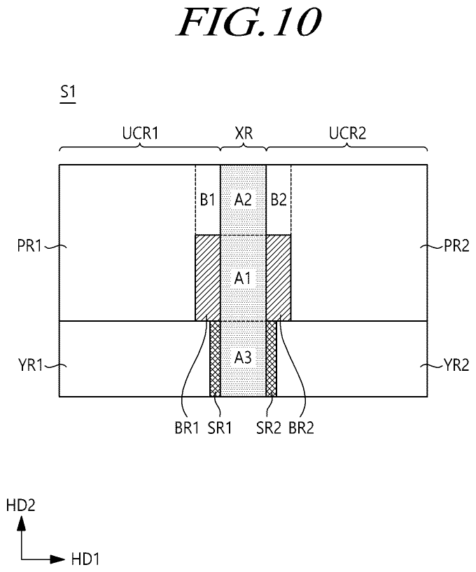

Referring to FIG. 10, the first under cell region UCR1 may further include a first switching element region SR1, and the second under cell region UCR2 may further include a second switching element region SR2.

The first and second switching element regions SR1 and SR2 are regions where the switching elements of the global row line decoder are disposed, and the switching elements of the global row line decoder may be grouped into two and disposed in the first switching element region SR1 and the second switching element region SR2. The first switching element region SR1 may be connected to the pass transistor region XR through first global word lines (not shown), and the second switching element region SR2 may be connected to the pass transistor region XR through second global word lines (not shown).

The first under cell region UCR1 may include the first block selection circuit region BR1, the first peripheral circuit region PR1, the first page buffer region YR1, and the first switching element region SR1. The second under cell region UCR2 may include a second block selection circuit region BR2, a second peripheral circuit region PR2, a second page buffer region YR2, and a second switching element region SR2.

The first switching element region SR1 may be disposed between the first page buffer region YR1 and the third portion A3 of the pass transistor region XR. The first switching element region SR1 may overlap with the first block selection circuit region BR1 in the second direction HD2.

The second switching element region SR2 may be disposed between the second page buffer region YR2 and the third portion A3 of the pass transistor region XR. The second switching element region SR2 may overlap with the second block selection circuit region BR2 in the second direction HD2.

According to an embodiment of the present disclosure, the first and second switching element regions SR1 and SR2 may be disposed to overlap with the first and second block selection circuit regions BR1 and BR2 in the second direction HD2, so that the first and second switching element regions SR1 and SR2 may be included in layer without increasing the dimension of the first semiconductor layer S1 in the first direction HD1.

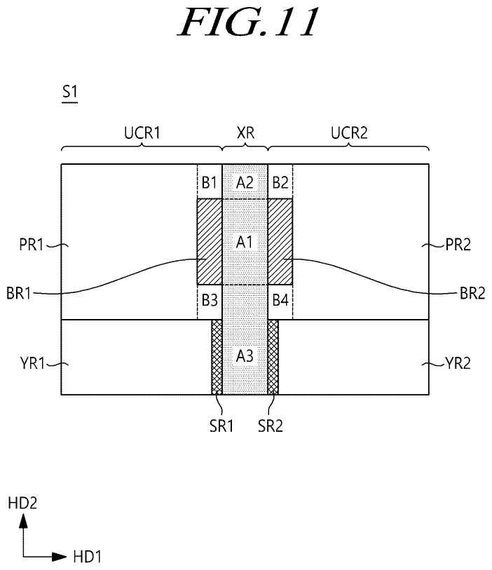

Referring to FIG. 11, a first peripheral circuit region PR1 may include a first region B1 and a third region B3 disposed on both sides of the first block selection circuit region BR1 in the second direction HD2. The second peripheral circuit region PR2 may include a second region B2 and a fourth region B4 disposed on both sides of the second block selection circuit region BR2 in the second direction HD2.

The first region B1 may overlap with the first block selection circuit region BR1 in the second direction HD2, and may overlap with the second portion A2 of the pass transistor region XR in the first direction HD1. The third region B3 may overlap with the first block selection circuit region BR1 in the second direction HD2, and may overlap with the third portion A3 of the pass transistor region XR in the first direction HD1.

The second region B2 may overlap with the second block selection circuit region BR2 in the second direction HD2, and may overlap with the second portion A2 of the pass transistor region XR in the first direction HD1. The fourth region B4 may overlap with the second block selection circuit region BR2 in the second direction HD2, and may overlap with the third portion A3 of the pass transistor region XR in the first direction HD1.

The first block selection circuit region BR1 may be spaced apart from the first switching element region SR1 and the first page buffer region YR1 in the second direction HD2. The third region B3 may be located in the second direction HD2 between the first block selection circuit region BR1 and the first switching element region SR1, and between the first block selection circuit region BR1 and the first page buffer region YR1.

The second block selection circuit region BR2 may be spaced apart from the second switching element region SR2 and the second page buffer region YR2 in the second direction HD2. A fourth region B4 may be located in the second direction HD2 between the second block selection circuit region BR2 and the second switching element region SR2, and between the second block selection circuit region BR2 and the second page buffer region YR2.

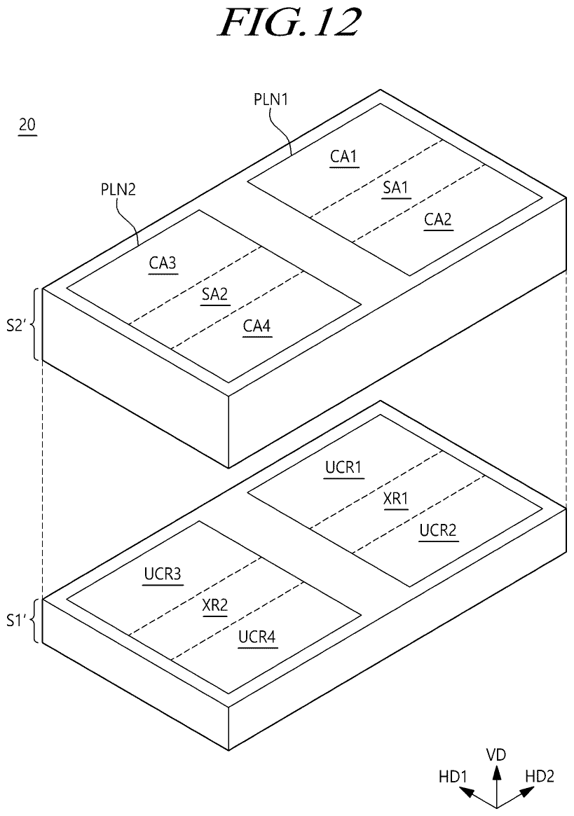

FIG. 12 is a perspective view of a memory device according to embodiments of the present disclosure.

Referring to FIG. 12, a memory device 20 may include a plurality of planes. In an embodiment, the memory device 20 may include two planes, and a second semiconductor layer S2′ may include a first plane area PLN1 and a second plane area PLN2.

The first plane area PLN1 may include a first cell area CA1, a second cell area CA2, and a first slimming area SA1. The first slimming area SA1 may be disposed at a center region of the first plane area PLN1, and the first cell area CA1 and the second cell area CA2 may be disposed on both sides of the first slimming area SA1 in the first direction HD1, respectively.

Although not illustrated, a plurality of first word lines may be stacked in a vertical direction VD in the first and second cell areas CA1 and CA2 and the first slimming area SA1 to form a first stacked body. The first word lines may be combined with first semiconductor pillars penetrating the first stacked body in a vertical direction VD to form first memory cells arranged three-dimensionally. The plurality of first word lines may be implemented in a step or stair shape in the first slimming area SA1.

The second plane area PLN2 may include a third cell area CA3, a fourth cell area CA4, and a second slimming area SA2. The second slimming area SA2 may be disposed in the center region of the second plane area PLN2, and the third cell area CA3 and the fourth cell area CA4 may be disposed on both sides of the second slimming area SA2 in the first direction HD1, respectively.

The first cell area CA1 and the third cell area CA3 may be disposed in a line along the second direction HD2. The second cell area CA2 and the fourth cell area CA4 may be disposed in a line along the second direction HD2. The first slimming area SA1 and the second slimming area SA2 may be disposed in a line along the second direction HD2.

Although not illustrated, a plurality of second word lines may be stacked in the vertical direction VD in the third and fourth cell areas CA3 and CA4 and the second slimming area SA2 to form a second stacked body. The second word lines may be combined with second semiconductor pillars penetrating the second stacked body in the vertical direction VD to form second memory cells arranged three-dimensionally. The plurality of second word lines may be implemented in a step or stair shape in the second slimming area SA2.

A first semiconductor layer S1′ may include a first under cell region UCR1 that overlaps with the first cell area CA1 in the vertical direction VD, a second under cell region UCR2 that overlaps with the second cell area CA2 in the vertical direction VD, a third under cell region UCR3 that overlaps with the third cell area CA3 in the vertical direction VD, a fourth under cell region UCR4 that overlaps with the fourth cell area CA4 in the vertical direction VD, a first pass transistor region XR1 that overlaps with the first slimming area SA1 in the vertical direction VD, and a second pass transistor region XR2 that overlaps with the second slimming area SA2 in the vertical direction VD.

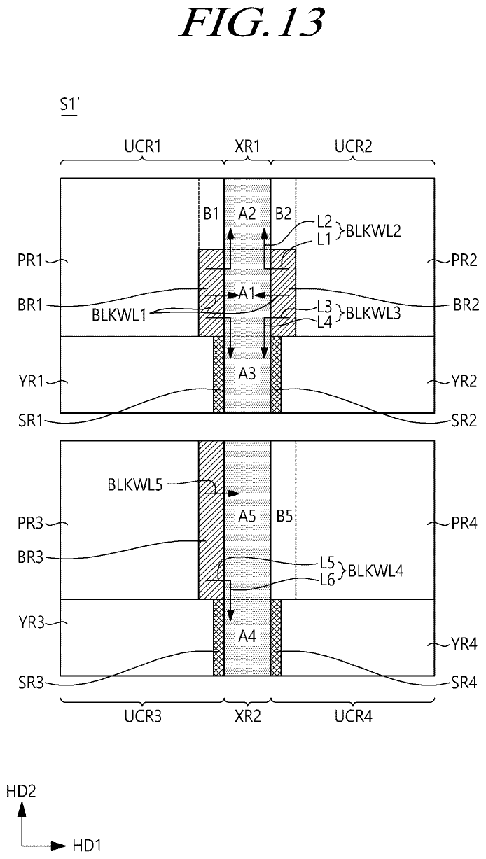

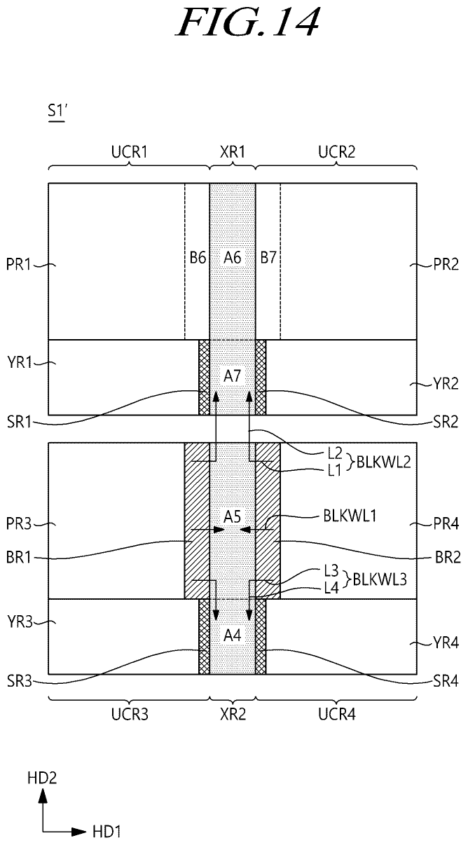

FIGS. 13 to 14 are schematic plan views of a first semiconductor layer according to embodiments of the present disclosure.

Referring to FIG. 13, a first under cell region UCR1 and the second under cell region UCR2 may be respectively disposed on both sides of the first pass transistor region XR1 in the first direction HD1. The third under cell region UCR3 and the fourth under cell region UCR4 may respectively be arranged on both sides of the second pass transistor region XR2 in the first direction HD1.

The first under cell region UCR1 and the third under cell region UCR3 may overlap with each other in the second direction HD2. The second under cell region UCR2 and the fourth under cell region UCR4 may overlap with each other in the second direction HD2. The first pass transistor region XR1 and the second pass transistor region XR2 may overlap with each other in the second direction HD2.

The first pass transistor region XR1 may be divided into a first portion A1, a second portion A2, and a third portion A3. The second portion A2 and the third portion A3 may be respectively disposed on both sides of the first portion A1 in the second direction HD2. The first pass transistor region XR1 may be connected to the first and second cell areas CA1 and CA2 of FIG. 12 through a plurality of first word lines (not shown).

A first block selection circuit region BR1 and a second block selection circuit region BR2 may be respectively disposed on both sides of the first portion A1 of the first pass transistor region XR1 in the first direction HD1. The first block selection circuit region BR1 may be included in the first under cell region UCR1, and the second block selection circuit region BR2 may be included in the second under cell region UCR2.

The first under cell region UCR1 may include a first block selection circuit region BR1, a first peripheral circuit region PR1, a first page buffer region YR1, and a first switching element region SR1. The second under cell region UCR2 may include a second block selection circuit region BR2, a second peripheral circuit region PR2, a second page buffer region YR2, and a second switching element region SR2.

The first page buffer region YR1 and the second page buffer region YR2 may be respectively disposed on both sides of the third portion A3 of the first pass transistor region XR1 in the first direction HD1. In an embodiment, the dimension in the second direction HD2 of the first and second page buffer regions YR1, YR2 may be substantially the same as the dimension in the second direction HD2 of the third portion A3 of the first pass transistor region XR1. The first and second page buffer regions YR1 and YR2 may be connected to the first and second cell areas CA1 and CA2 of FIG. 12 through a plurality of first bit lines (not shown).

The first switching element region SR1 may be disposed between the first page buffer region YR1 and the third portion A3 of the first pass transistor region XR1. The first switching element region SR1 may overlap with the first block selection circuit region BR1 in the second direction HD2. The first switching element region SR1 may overlap with the third block selection circuit region BR3 described below in the second direction HD2. The second switching element region SR2 may be disposed between the second page buffer region YR2 and the third portion A3 of the first pass transistor region XR1. The second switching element region SR2 may overlap with the second block selection circuit region BR2 in the second direction HD2. The first switching element region SR1 may be connected to the first pass transistor region XR1 through first global word lines (not shown), and the second switching element region SR2 may be connected to the first pass transistor region XR1 through second global word lines (not shown).

In an embodiment, the first peripheral circuit region PR1 may be a portion remaining in the first under cell region UCR1 except for the first block selection circuit region BR1, the first page buffer region YR1, and the first switching element region SR1. The second peripheral circuit region PR2 may be a portion remaining in the second under cell region UCR2 except for the second block selection circuit region BR2, the second page buffer region YR2, and the second switching element region SR2.

The first peripheral circuit region PR1 may include a first region B1 overlapping with the first block selection circuit region BR1 in the second direction HD2. The second peripheral circuit region PR2 may include a second region B2 overlapping with the second block selection circuit region BR2 in the second direction HD2. The first region B1 and the second region B2 may be in contact with both sides of the second portion A2 of the first pass transistor region XR1 in the first direction HD1.

The second pass transistor region XR2 may be divided into a fourth portion A4 and a fifth portion A5. The fifth portion A5 may be disposed between the first pass transistor region XR1 and the fourth portion A4. The second pass transistor region XR2 may be connected to the third and fourth cell areas CA3 and CA4 of FIG. 12 through a plurality of second word lines (not shown).

A third block selection circuit region BR3 may be disposed on one side of the fifth portion A5 of the second pass transistor region XR2 in the first direction HD1. The third block selection circuit region BR3 may be included in the third under cell region UCR1. The fourth under cell region UCR4 may not include the block selection circuit region.

The third under cell region UCR3 may include a third block selection circuit region BR3, a third peripheral circuit region PR3, a third page buffer region YR3, and a third switching element region SR3. The fourth under cell region UCR4 may include a fourth peripheral circuit region PR4, a fourth page buffer region YR4, and a fourth switching element region SR4.

The third page buffer region YR3 and the fourth page buffer region YR4 may be respectively disposed on both sides of the fourth portion A4 of the second pass transistor region XR2 in the first direction HD1. In an embodiment, the dimensions in the second direction HD2 of the third and fourth page buffer regions YR3 and YR4 may be substantially the same as the dimension in the second direction HD2 of the fourth portion A4 of the second pass transistor region XR2. The third and fourth page buffer regions YR3 and YR4 may be connected to the third and fourth cell areas CA3 and CA4 of FIG. 12 through a plurality of second bit lines (not shown).

The third switching element region SR3 may be disposed between the third page buffer region YR3 and the fourth portion A4 of the second pass transistor region XR2. The third switching element region SR3 may overlap with the first and third block selection circuit regions BR1 and BR3 in the second direction HD2. The fourth switching element region SR4 may be disposed between the fourth page buffer region YR4 and the fourth portion A4 of the second pass transistor region XR2. The fourth switching element region SR4 may overlap with the second block selection circuit region BR2 in the second direction HD2. The third switching element region SR3 may be connected to the second pass transistor region XR2 through third global word lines (not shown), and the fourth switching element region SR4 may be connected to the second pass transistor region XR2 through fourth global word lines (not shown).

The third peripheral circuit region PR3 may be the remaining portion of the third under cell region UCR3 excluding the third block selection circuit region BR3, the third page buffer region YR3, and the third switching element region SR3. The third block selection circuit region BR3 may be disposed between the third peripheral circuit region PR3 and the second pass transistor region XR2. The dimension of the third block selection circuit region BR3 in the second direction HD2 may be substantially the same as the dimension of the third peripheral circuit region PR3 in the second direction HD2.

The fourth peripheral circuit region PR4 may be a region remaining in the fourth under cell region UCR4 excluding the fourth page buffer region YR4 and the fourth switching element region SR4. The fourth peripheral circuit region PR4 may include a fifth region B5 overlapping with the second block selection circuit region BR2 in the second direction HD2. The dimension of the fourth peripheral circuit region PR4 in the first direction HD1 may be substantially the same as the dimension of the fourth under cell region UCR4 in the first direction HD1.

The block selection signal lines BLKWL1, BLKWL2, BLKWL3, BLKWL4 and BLKWL5 may include a first block selection signal line BLKWL1, a second block selection signal line BLKWL2, a third block selection signal line BLKWL3, a fourth block selection signal line BLKWL4, and a fifth block selection signal line BLKWL5.

The first block selection signal line BLKWL1 may be connected to a first portion A1 of the first pass transistor region XR1. The second block selection signal line BLKWL2 may be connected to a second portion A2 of the first pass transistor region XR1. The third block selection signal line BLKWL3 may be connected to a third portion A3 of the first pass transistor region XR1. The fourth block selection signal line BLKWL4 may be connected to the fourth portion A4 of the second pass transistor region XR2. The fifth block selection signal line BLKWL5 may be connected to the fifth portion A5 of the second pass transistor region XR2.

In a plan view, the first block selection signal line BLKWL1 may extend from one of the first block selection circuit region BR1 and the second block selection circuit region BR2, along the first direction HD1, to the first portion A1 of the first pass transistor region XR1.

In a plan view, the second block selection signal line BLKWL2 may include a first line portion L1 extending from one of the first block selection circuit region BR1 and the second block selection circuit region BR2 along the first direction HD1 to the first portion A1 of the first pass transistor region XR1, which is connected to a second line portion L2 extending from the first portion A1 of the first pass transistor region XR1 along the second direction HD2 to the second portion A2 of the first pass transistor region XR1.

In a plan view, the third block selection signal line BLKWL3 may include a third line portion L3 extending from one of the first block selection circuit region BR1 and the second block selection circuit region BR2 along the first direction HD1 to the first portion A1 of the first pass transistor region XR1, which is connected to a fourth line portion L4 extending from the first portion A1 of the first pass transistor region XR1 along the second direction HD2 to the third portion A3 of the first pass transistor region XR1.

In a plan view, the second line portion L2 of the second block selection signal line BLKWL2 and the fourth line portion L4 of the third block selection signal line BLKWL3 may extend in opposite directions in the second direction HD2 from a center area of the first portion A1 of the first pass transistor region XR1.

In a plan view, the fourth block selection signal line BLKWL4 may include a fifth line portion L5 extending from the third block selection circuit region BR3 along the first direction HD1 to the fifth portion A5 of the second pass transistor region XR2, which is connected to a sixth line portion L6 extending from the fifth portion A5 of the second pass transistor region XR2 along the second direction HD2 to the fourth portion A4 of the second pass transistor region XR2.

In a plan view, the fifth block selection signal line BLKWL5 may extend from the third block selection circuit region BR3 along the first direction HD1 to the fifth portion A5 of the second pass transistor region XR2.

The second line portion L2 of the second block selection signal line BLKWL2, the fourth line portion L4 of the third block selection signal line BLKWL3, and the sixth line portion L6 of the fourth block selection signal line BLKWL4, all extending in the second direction HD2, may be disposed in a different wiring layer from the first block selection signal line BLKWL1, the first line portion L1 of the second block selection signal line BLKWL2, the third line portion L3 of the third block selection signal line BLKWL3, the fifth line portion L5 of the fourth block selection signal line BLKWL4, and the fifth block selection signal line BLKWL5 extending in the first direction HD1. For example, the first semiconductor layer S1′ may include a first wiring layer and a second wiring layer that are disposed at different vertical heights, and the first block selection signal line BLKWL1, the first line portion L1 of the second block selection signal line BLKWL2, the third line portion L3 of the third block selection signal line BLKWL3, the fifth line portion L5 of the fourth block selection signal line BLKWL4 and the fifth block selection signal line BLKWL5 may be disposed in the first wiring layer. The second line portion L2 of the second block selection signal line BLKWL2, the fourth line portion L4 of the third block selection signal line BLKWL3, and the sixth line portion L6 of the fourth block selection signal line BLKWL4 may be disposed in the second wiring layer.

On the first pass transistor region XR1, the second line portion L2 of the second block selection signal line BLKWL2 and the fourth line portion L4 of the third block selection signal line BLKWL3 may extend in opposite direction along the second direction HD2 centered on the first portion A1 of the pass transistor region XR. On the second pass transistor region XR2, the sixth line portion L6 of the fourth block selection signal line BLKWL4 may extend in the opposite direction from the first pass transistor region XR1. Accordingly, the second line portion L2 of the second block selection signal line BLKWL2, the fourth line portion L4 of the third block selection signal line BLKWL3, and the sixth line portion L6 of the fourth block selection signal line BLKWL4 can be disposed without overlapping with each other in the second direction HD2, and the second line portions L2 of the N second block selection signal lines BLKWL2, the fourth line portions L4 of the N third block selection signal lines BLKWL3, and the sixth line portions L6 of the N fourth block selection signal lines BLKWL4 may all be disposed in an area corresponding to N times the wiring pitch.

Referring to FIG. 14, a first pass transistor region XR1 may be divided into a sixth portion A6 and a seventh portion A7. The seventh portion A7 may be disposed between the second pass transistor region XR2 and the sixth portion A6.

The first under cell region UCR1 may include a first peripheral circuit region PR1, a first page buffer region YR1, and a first switching element region SR1. The second under cell region UCR2 may include a second peripheral circuit region PR2, a second page buffer region YR2, and a second switching element region SR2. The first and second under cell regions UCR1 and UCR2 may not include a block selection circuit region.

The first page buffer region YR1 and the second page buffer region YR2 may be disposed on both sides of the seventh portion A7 of the first pass transistor region XR1 in the first direction HD1, respectively.

The first switching element region SR1 may be disposed between the seventh portion A7 of the first pass transistor region XR1 and the first page buffer region YR1 in the first direction HD1. The first switching element region SR1 may overlap with the first block selection circuit region BR1 described later in the second direction HD2. The second switching element region SR2 may be disposed between the seventh portion A7 of the first pass transistor region XR1 and the second page buffer region YR2 in the first direction HD1. The second switching element region SR2 may overlap with the second block selection circuit region BR2 described later in the second direction HD2.

The first peripheral circuit region PR1 may be the remaining portion of the first under cell region UCR1 excluding the first page buffer region YR1 and the first switching element region SR1. The second peripheral circuit region PR2 may be the remaining portion of the second under cell region UCR2 excluding the second page buffer region YR2 and the second switching element region SR2.

The first peripheral circuit region PR1 may include a sixth region B6 that overlaps with the first block selection circuit region BR1 described below in the second direction HD2. The second peripheral circuit region PR2 may include a seventh region B7 that overlaps with the second block selection circuit region BR2 described below in the second direction HD2. The first peripheral circuit region PR1 and the second peripheral circuit region PR2 may be in contact with both sides of the first pass transistor region XR1 in the first direction HD1.

The dimension in the first direction HD1 of the first peripheral circuit region PR1 may be substantially the same as the dimension in the first direction HD1 of the first under cell region UCR1, and the dimension in the first direction HD1 of the second peripheral circuit region PR2 may be substantially the same as the dimension in the first direction HD1 of the second under cell region UCR2.

Since the first under cell region UCR1 and the second under cell region UCR2 do not include a block selection circuit region, the area of the first and second peripheral circuit regions PR1 and PR2 may be increased compared to a first under cell region UCR1 and the second under cell region UCR2 that each include a block selection circuit region.

The second pass transistor region XR2 may be divided into a fourth portion A4 and a fifth portion A5. The fifth portion A5 may be disposed between the fourth portion A4 and the first pass transistor region XR1.

The first block selection circuit region BR1 and the second block selection circuit region BR2 may be disposed on both sides of the fifth portion A5 of the second pass transistor region XR2 in the first direction HD1. The first block selection circuit region BR1 may be included in the third under cell region UCR3, and the second block selection circuit region BR2 may be included in the fourth under cell region UCR4.

The third under cell region UCR3 may include a first block selection circuit region BR1, a third peripheral circuit region PR3, a third page buffer region YR3, and a third switching element region SR3. The fourth under cell region UCR4 may include a second block selection circuit region BR2, a fourth peripheral circuit region PR4, a fourth page buffer region YR4, and the fourth switching element region SR4.

The third switching element region SR3 may be disposed between the fourth portion A4 of the second pass transistor region XR2 and the third page buffer region YR3. The third switching element region SR3 may overlap with the first block selection circuit region BR1 in the second direction HD2.

The fourth switching element region SR4 may be disposed between the fourth portion A4 of the second pass transistor region XR2 and the fourth page buffer region YR4. The fourth switching element region SR4 may overlap with the second block selection circuit region BR2 in the second direction HD2.

The third peripheral circuit region PR3 may be a remaining portion of the third under cell region UCR3 excluding the first block selection circuit region BR1, the third page buffer region YR3, and the third switching element region SR3. The fourth peripheral circuit region PR4 may be a remaining portion of the fourth under cell region UCR4 excluding the second block selection circuit region BR2, the fourth page buffer region YR4, and the fourth switching element region SR4.

The dimensions in the second direction HD2 of the first and second block selection circuit regions BR1 and BR2 may be substantially the same as the dimensions in the second direction HD2 of the first and second peripheral circuit regions PR1 and PR2.

The block selection signal lines BLKWL1, BLKWL2 and BLKWL3 may include first block selection signal lines BLKWL1, second block selection signal lines BLKWL2, and third block selection signal lines BLKWL3.

The first block selection signal lines BLKWL1 may be connected to the fifth portion A5 of the second pass transistor region XR2. The second block selection signal lines BLKWL2 may be connected to the first pass transistor region XR1. The third block selection signal lines BLKWL3 may be connected to the fourth portion A4 of the second pass transistor region XR2.

In a plan view, the first block selection signal line BLKWL1 may extend from one of the first and second block selection circuit regions BR1 and BR2 along the first direction HD1 to the fifth portion A5 of the second pass transistor region XR2.

In a plan view, the second block selection signal line BLKWL2 may include a first line portion L1 extending from one of the first and second block selection circuit regions BR1 and BR2 along the first direction HD1 to the fifth portion A5 of the second pass transistor region XR2, which connects to a second line portion L2 extending from the fifth portion A5 of the second pass transistor region XR2 along the second direction HD2 to the seventh portion A7 of the first pass transistor region XR1.

In a plan view, the third block selection signal line BLKWL3 may include a third line portion L3 extending from one of the first and second block selection circuit regions BR1 and BR2 along the first direction HD1 to the fifth portion A5 of the second pass transistor region XR2, which is connected to a fourth line portion L4 extending from the fifth portion A5 of the second pass transistor region XR2 along the second direction HD2 to the fourth portion A4 of the second pass transistor region XR2.

The first block selection signal line BLKWL1, the first line portion L1 of the second block selection signal line BLKWL2, and the third line portion L3 of the third block selection signal line BLKWL3 extending in the first direction HD1 may be disposed in a different wiring layer from the second line portion L2 of the second block selection signal line BLKWL2 and the fourth line portion L4 of the third block selection signal line BLKWL3 extending in the second direction HD2. For example, the first semiconductor layer S1′ may include a first wiring layer and a second wiring layer disposed at different vertical heights, and the first block selection signal line BLKWL1, the first line portion L1 of the second block selection signal line BLKWL2 and the third line portion L3 of the third block selection signal line BLKWL3 may be disposed in the first wiring layer, and the second line portion L2 of the second block selection signal line BLKWL2 and the fourth line portion L4 of the third block selection signal line BLKWL3 may be disposed in the second wiring layer.

In a plan view, the second line portion L2 of the second block selection signal line BLKWL2 and the fourth line portion L4 of the third block selection signal line BLKWL3 may extend in opposite directions along the second direction HD2 from a center are of the fifth portion A5 of the second pass transistor region XR2.

Since the second line portion L2 of the second block selection signal line BLKWL2 and the fourth line portion L4 of the third block selection signal line BLKWL3 extend in opposite directions, the second line portions L2 of the N second block selection signal lines BLKWL2 and the fourth line portions L4 of the N third block selection signal lines BLKWL3 may all be disposed in an area corresponding to N times the wiring pitch.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical ideas of this disclosure but to explain the technical ideas of this disclosure, the scope of the technical ideas of this disclosure is not limited by these embodiments. The protection scope of this disclosure should be interpreted by the claims below, and all technical ideas within the equivalent scope should be interpreted as being included in the scope of the rights of this disclosure.

What is claimed is:

1. A memory device comprising:
a first semiconductor layer including a slimming area, a first cell area and a second cell area arranged on both sides of the slimming area in a first direction; and
a second semiconductor layer including a pass transistor region vertically overlapping with the slimming area, and a first block selection circuit region and a second block selection circuit region connected to the pass transistor region through a plurality of block selection signal lines,
wherein the pass transistor region includes a first portion, and a second portion and a third portion disposed on both sides of the first portion in a second direction perpendicular to the first direction,
wherein the first block selection circuit region and the second block selection circuit region are respectively disposed on both sides of the first portion of the pass transistor region in the first direction.

2. The memory device of claim 1, wherein the plurality of block selection signal lines include:
a first block selection signal line including a first line portion extending from the first portion of the pass transistor region along the second direction to the second portion of the pass transistor region; and
a second block selection signal line including a second line portion extending from the first portion of the pass transistor region along the second direction to the third portion of the pass transistor region.

3. The memory device of claim 1, wherein the second semiconductor layer include:
a first under cell region vertically overlapping with the first cell area; and
a second under cell region vertically overlapping with the second cell area,
wherein the first block selection circuit region is included in the first under cell region, and the second block selection circuit region is included in the second under cell region.

4. The memory device of claim 3, wherein the first under cell region further includes a first peripheral circuit region, and the second under cell region further includes a second peripheral circuit region,
wherein the first peripheral circuit region includes a first region overlapping with the first block selection circuit region in the second direction,
wherein the second peripheral circuit region includes a second region overlapping with the second block selection circuit region in the second direction.

5. The memory device of claim 4, wherein the first region and the second region are respectively in contact with both sides of the second portion of the pass transistor region in the first direction.

6. The memory device of claim 3, wherein the first under cell region further includes a first peripheral circuit region, and the second under cell region further includes a second peripheral circuit region,
wherein the first peripheral circuit region includes a first region and a second region disposed on both sides of the first block selection circuit region in the second direction,
wherein the second peripheral circuit region includes a third region and a fourth region disposed on both sides of the second block selection circuit region in the second direction.

7. The memory device of claim 6, wherein the first region and the third region are respectively in contact with both sides of the second portion of the pass transistor region in the first direction,
wherein the second region and the fourth region are respectively in contact with both sides of the third portion of the pass transistor region in the first direction.

8. The memory device of claim 3, wherein the first under cell region further includes a first switching element region connected to the pass transistor region through a plurality of first global word lines,
wherein the second under cell region further includes a second switching element region connected to the pass transistor region through a plurality of second global word lines,
wherein the first switching element region overlaps with the first block selection circuit region in the second direction,
wherein the second switching element region overlaps with the second block selection circuit region in the second direction.

9. The memory device of claim 8, wherein the first under cell region further includes a first page buffer region, and the second under cell region further includes a second page buffer region,
wherein the first switching element region is disposed between the first page buffer region and the pass transistor region,
wherein the second switching element region is disposed between the second page buffer region and the pass transistor region.

10. A memory device comprising:
a first semiconductor layer including a first slimming area, a first plane area including a first cell area and a second cell area respectively disposed on both sides of the first slimming area in a first direction, a second slimming area arranged in a second direction perpendicular to the first direction from the first slimming area, and a second plane area including a third cell area and a fourth cell area respectively disposed on both sides of the second slimming area in the first direction; and
a second semiconductor layer including a first pass transistor region vertically overlapping with the first slimming area, a second pass transistor region vertically overlapping with the second slimming area, and a first block selection circuit region, a second block selection circuit region and a third block selection circuit region connected to the first pass transistor region and the second pass transistor region through a plurality of block selection signal lines,
wherein the first pass transistor region includes a first portion, a second portion and a third portion disposed on both sides of the first portion in the second direction,
wherein the second pass transistor region includes a fourth portion, and a fifth portion between the first pass transistor region and the fourth portion,
wherein the first block selection circuit region and the second block selection circuit region are disposed on both sides of the first portion of the first pass transistor region in the first direction, respectively,
wherein the third block selection circuit region is disposed on one side of the fifth portion of the second pass transistor region in the first direction.

11. The memory device of claim 10, wherein the plurality of block selection signal lines include:
a first block selection signal line including a first line portion extending from the first portion of the first pass transistor region along the second direction to the second portion of the first pass transistor region;
a second block selection signal line including a second line portion extending from the first portion of the first pass transistor region along the second direction to the third portion of the first pass transistor region; and
a third block selection signal line including a third line portion extending from the fifth portion of the second pass transistor region along the second direction to the fourth portion of the second pass transistor region.

12. The memory device of claim 10, wherein the second semiconductor layer includes:
a first under cell region vertically overlapping with the first cell area;
a second under cell region vertically overlapping with the second cell area;
a third under cell region vertically overlapping with the third cell area; and
a fourth under cell region vertically overlapping with the fourth cell area,
wherein the first block selection circuit region is included in the first under cell region,
wherein the second block selection circuit region is included in the second under cell region,
wherein the third block selection circuit region is included in the third under cell region.

13. The memory device of claim 12, wherein the first under cell region further includes a first peripheral circuit region,
wherein the second under cell region further includes a second peripheral circuit region,
wherein the third under cell region further includes a third peripheral circuit region,
wherein the fourth under cell region further includes a fourth peripheral circuit region,
wherein the first peripheral circuit region includes a first region overlapping with the first block selection circuit region in the second direction,
wherein the second peripheral circuit region includes a second region overlapping with the second block selection circuit region in the second direction,
wherein the fourth peripheral circuit region includes a third region overlapping with the second block selection circuit region in the second direction.

14. The memory device of claim 12, wherein the first under cell region further includes a first switching element region connected to the first pass transistor region through a plurality of first global word lines,
wherein the second under cell region further includes a second switching element region connected to the first pass transistor region through a plurality of second global word lines,
wherein the third under cell region further includes a third switching element region connected to the second pass transistor region through a plurality of third global word lines,
wherein the fourth under cell region further includes a fourth switching element region connected to the second pass transistor region through a plurality of fourth global word lines,
wherein the first switching element region and the third switching element region overlap with the first block selection circuit region and the third block selection circuit region in the second direction,
wherein the second switching element region and the fourth switching element region overlap with the second block selection circuit region in the second direction.

15. A memory device comprising:
a first semiconductor layer including a first slimming area, a first plane area including a first cell area and a second cell area respectively disposed on both sides of the first slimming area in a first direction, a second slimming area adjacent to the first slimming area in a second direction, and a second plane area including a third cell area and a fourth cell area respectively disposed on both sides of the second slimming area in the first direction; and
a second semiconductor layer including a first pass transistor region vertically overlapping with the first slimming area, a second pass transistor region vertically overlapping with the second slimming area, and a first block selection circuit region and a second block selection circuit region connected to the first pass transistor region and the second pass transistor region through a plurality of block selection signal lines,
wherein the second pass transistor region includes a first portion, and a second portion between the first pass transistor region and the first portion,
wherein the first block selection circuit region and the second block selection circuit region are respectively disposed on both sides of the second portion of the second pass transistor region in the first direction.

16. The memory device of claim 15, wherein the plurality of block selection signal lines include:
a first block selection signal line including a first line portion extending from the second portion of the second pass transistor region along the second direction to the first pass transistor region; and
a second block selection signal line including a second line portion extending from the second portion of the second pass transistor region along the second direction to the first portion of the second pass transistor region.

17. The memory device of claim 15, wherein the second semiconductor layer includes:
a first under cell region vertically overlapping with the first cell area;
a second under cell region vertically overlapping with the second cell area;
a third under cell region vertically overlapping with the third cell area; and
a fourth under cell region vertically overlapping the fourth cell area,
wherein the first block selection circuit region is included in the third under cell region,
wherein the second block selection circuit region is included in the fourth under cell region.

18. The memory device of claim 17, wherein the first under cell region further includes a first peripheral circuit region,
wherein the second under cell region further includes a second peripheral circuit region,
wherein the first peripheral circuit region includes a first region overlapping with the first block selection circuit region in the second direction,
wherein the second peripheral circuit region includes a second region overlapping with the second block selection circuit region in the second direction.

19. The memory device of claim 18, wherein the third under cell region further includes a third peripheral circuit region,
wherein the fourth under cell region further includes a fourth peripheral circuit region,
wherein the first block selection circuit region is disposed between the third peripheral circuit region and the second portion of the second pass transistor region,
wherein the second block selection circuit region is disposed between the fourth peripheral circuit region and the second portion of the second pass transistor region.

20. The memory device of claim 17, wherein the first under cell region further includes a first switching element region connected to the first pass transistor region through a plurality of first global word lines,
wherein the second under cell region further includes a second switching element region connected to the first pass transistor region through a plurality of second global word lines,
wherein the third under cell region further includes a third switching element region connected to the second pass transistor region through a plurality of third global word lines,
wherein the fourth under cell region further includes a fourth switching element region connected to the second pass transistor region through a plurality of fourth global word lines,
wherein the first switching element region and the third switching element region overlap with the first block selection circuit region in the second direction,
wherein the second switching element region and the fourth switching element region overlap with the second block selection circuit region in the second direction.
